(19) United States
(12) Patent Application Publication
(10) Pub. No.: US 2025/0159992 A1
(43) Pub. Date: May 15, 2025

(54) ARRAY SUBSTRATE AND DISPLAY PANEL

(71) Applicant: Sharp Display Technology Corporation, Kameyama City (JP)

(72) Inventors: Takushi SHINOHARA, Kameyama City (JP); Yuhichi SAITOH, Kameyama City (JP)

(21) Appl. No.: 18/920,057

(22) Filed: Oct. 18, 2024

(30) Foreign Application Priority Data
Nov. 13, 2023 (JP) 2023-192997

(51) Int. Cl. H01L 27/12; G02F 1/1368

(52) U.S. Cl. CPC H10D 86/60; G02F 1/1368; H10D 86/451; G02F 2202/104

(57) ABSTRACT

An array substrate includes a first TFT that includes a first insulation film, a first semiconductor film in a layer upper than the first insulation film, a second insulation film in a layer upper than the first semiconductor film, a first gate electrode in a layer upper than the second insulation film and overlapping the first semiconductor film, a third insulation film in a layer upper than the first gate electrode, a first source electrode and a first drain electrode that are portions of a metal film in a layer upper than the third insulation film and connected to the first semiconductor film via first contact holes in the third insulation film, and an auxiliary film made of non-metal material and in a layer upper or lower than the first semiconductor film to overlap at least lower surfaces of the first source electrode and the first drain electrode.

### CROSS REFERENCE TO RELATED APPLICATION

This application claims priority from Japanese Patent Application No. 2023-192997 filed on Nov. 13, 2023. The entire contents of the priority application are incorporated herein by reference.

### TECHNICAL FIELD

The present technology described herein relates to an array substrate and a display device.

### BACKGROUND

It has been known that thin film transistors (TFTs) are used as switching components in a display panel such as a liquid crystal panel and an organic electro-luminescence (EL) panel. The TFT includes various kinds of thin films formed in layers on an array substrate (an active matrix substrate, a TFT substrate). It has been known that two different kinds of TFTs are formed on one substrate.

One example of a semiconductor device includes first TFTs and second TFTs. The first TFT includes a channel made of a first polysilicon and a source and a drain made of a second polysilicon. The second polysilicon is obtained by adding conductivity to the first polysilicon. The second TFT includes a channel made of oxide semiconductor and a source and a drain made of the oxide semiconductor having conductivity. A metal protection film is formed on portions of the oxide semiconductor film of the second TFT that are connected to the drain electrode and the source electrode. The metal protection film is for protecting the oxide semiconductor film from hydrofluoric acid that is used for cleaning through holes for connection of the drain electrodes and the source electrodes. Accordingly, the oxide semiconductor film is less likely to be deteriorated.

When forming the metal protection film, the metal protection film needs to include some margins and to be formed with a larger size because the planar patterns may be varied and positions of the planar patterns of the components may not match in the actual manufacturing. However, with increasing the planar size of the metal protection film that has light blocking properties, the opening ratio may be reduced.

### SUMMARY

The technology described herein was made in view of the above circumstances. An object is to protect a semiconductor film of a TFT without reducing an opening ratio.
(1) An array substrate according to the technology described herein includes an insulating substrate and a first TFT. The first TFT includes a first insulation film disposed on an upper layer side of the insulating substrate, a first semiconductor film disposed in a layer upper than a layer including the first insulation film, a second insulation film disposed in a layer upper than the layer including the first semiconductor film, a first gate electrode disposed in a layer upper than the layer including the second insulation film and overlapping the first semiconductor film, a third insulation film disposed in a layer upper than the layer including the first gate electrode, a first source electrode and a first drain electrode that are portions of a metal film that is disposed in a layer upper than the layer including the third insulation film, the first source electrode and the first drain electrode being connected to the first semiconductor film via first contact holes that are through the third insulation film, and an auxiliary film made of non-metal material and disposed in a layer upper or lower than the layer including the first semiconductor film to overlap at least lower surfaces of the first source electrode and the first drain electrode.
(2) In the array substrate, in addition to (1), the auxiliary film may be included in the layer upper than the layer including the first semiconductor film and made of transparent conductive material.
(3) In the array substrate, in addition to (1), the auxiliary film may be included in the layer lower than the layer including the first semiconductor film and made of material same as that of the first semiconductor film.
(4) The array substrate may further include, in addition to any one of (1) to (3), a first light blocking portion disposed in a layer lower than the layer including the first insulation film, the first light blocking portion overlapping the first gate electrode and not overlapping the lower surfaces of the first source electrode and the first drain electrode.
(5) The array substrate may further include, in addition to any one of (1) to (4), the first TFT may further include a second gate electrode disposed in a layer lower than the layer including the first insulation film and the first TFT has a double gate structure.
(6) The array substrate may further include, in addition to (5), a second TFT that includes a second semiconductor film, a gate insulation film disposed in a layer upper than a layer including the second semiconductor film, a third gate electrode disposed in a layer upper than the layer including the gate insulation film and made of same material as material of the second gate electrode, the first insulation film disposed in the layer upper than the layer including the third gate electrode, the third insulation film disposed in the layer upper than the first insulation film, and a second source electrode and a second drain electrode connected to the second semiconductor film via second contact holes that are through the third insulation film, the first insulation film, and the gate insulation film. The first semiconductor film of the first TFT may be made of oxide semiconductor material and the second semiconductor film of the second TFT may be made of polysilicon semiconductor material.
(7) A display panel according to the technology described herein includes the array substrate according to any one of (1) to (6) and an opposed substrate opposed to the array substrate with having an inner space therebetween.

According to the technology described herein, a semiconductor film of a TFT can be protected without reducing an opening ratio.

### BRIEF DESCRIPTION OF THE DRAWINGS

FIG. 1 is a plan view illustrating a liquid crystal panel according to a first embodiment.

FIG. 2 is a cross-sectional view of the liquid crystal panel.

FIG. 3 is a circuit diagram illustrating a pixel arrangement of an array substrate in a display area.

FIG. 4 is a cross-sectional view of a portion of the array substrate including a first TFT and a second TFT.

FIG. 5 is an enlarged cross-sectional view of the portion including the first TFT in FIG. 4.

FIG. 6A is a cross-sectional view of a substrate that is in one of steps of a producing process of the array substrate in FIG. 4.

FIG. 6B is a cross-sectional view of a substrate that is in one of the steps of the producing process of the array substrate after FIG. 6A.

FIG. 6C is a cross-sectional view of a substrate that is in one of the steps of the producing process of the array substrate after FIG. 6B.

FIG. 6D is a cross-sectional view of a substrate that is in one of the steps of the producing process of the array substrate after FIG. 6C.

FIG. 6E is a cross-sectional view of a substrate that is in one of the steps of the producing process of the array substrate after FIG. 6D.

FIG. 6F is a cross-sectional view of a substrate that is in one of the steps of the producing process of the array substrate after FIG. 6E.

FIG. 7A is a cross-sectional view of a substrate that is in one of steps of a producing process of an array substrate of Comparative Example 1.

FIG. 7B is a cross-sectional view of a substrate that is in one of the steps of the producing process of the array substrate after FIG. 7A.

FIG. 8 is an enlarged cross-sectional view of a first TFT of an array substrate according to a second embodiment.

FIG. 9A is a cross-sectional view of a substrate that is in one of steps of a producing process of the array substrate in FIG. 8.

FIG. 9B is a cross-sectional view of a substrate that is in one of the steps of the producing process of the array substrate after FIG. 9A.

FIG. 9C is a cross-sectional view of a substrate that is in one of the steps of the producing process of the array substrate after FIG. 9B.

FIG. 9D is a cross-sectional view of a substrate that is in one of the steps of the producing process of the array substrate after FIG. 9C.

FIG. 9E is a cross-sectional view of a substrate that is in one of the steps of the producing process of the array substrate after FIG. 9D.

FIG. 10 is an enlarged cross-sectional view of a first TFT of an array substrate according to other embodiment.

### DETAILED DESCRIPTION

### First Embodiment

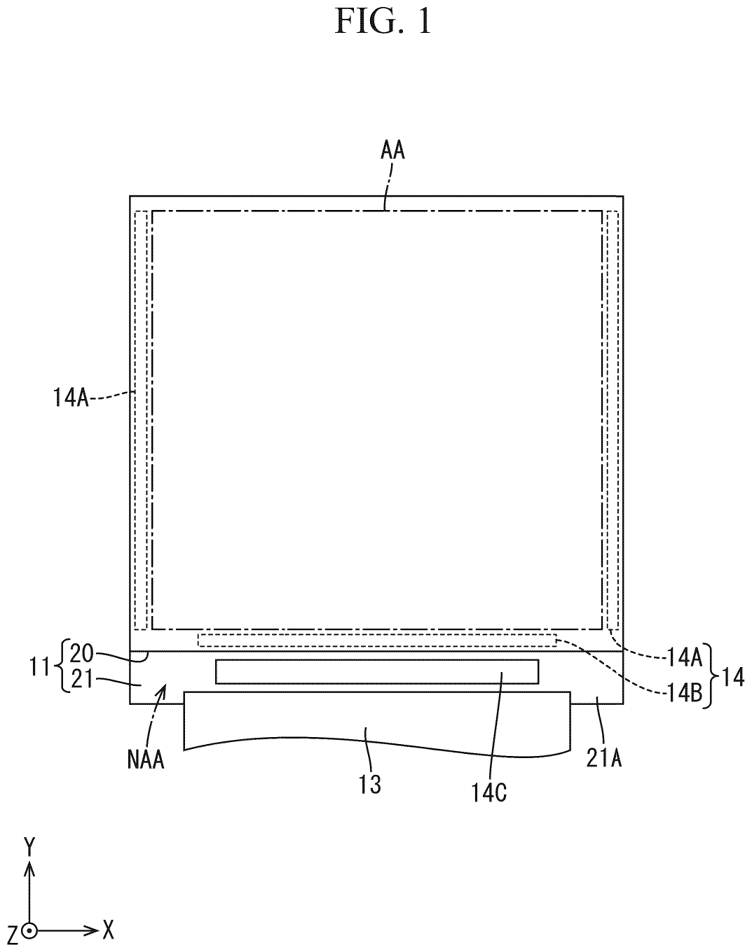

A liquid crystal panel 11 (one example of a display panel) according to a first embodiment will be described with reference to FIGS. 1 to 6F. X-axes, Y-axes, and Z-axes may be present in the drawings. The axes in each drawing correspond to the respective axes in other drawings.

As illustrated in FIG. 1, an inner surface of the liquid crystal panel 11 is divided into a display area AA (an active area) and a non-display area NAA (a non-active area). The display area AA is a middle section of the inner surface and images are displayed on the display area AA. The non-display area NAA is an outer section in a frame plan view shape surrounding the display area AA. In FIG. 1, the outline of the display area AA is illustrated with a chain line and an area outside the chain line is the non-display area NAA. The planar shape of the liquid crystal panel 11 is not limited to a special shape. The liquid crystal panel 11 has a vertically long rectangular plan view shape as a whole. A short-side direction corresponds to the X-axis direction, a long-side direction corresponds to the Y-axis direction, and a thickness direction corresponds to the Z-axis direction.

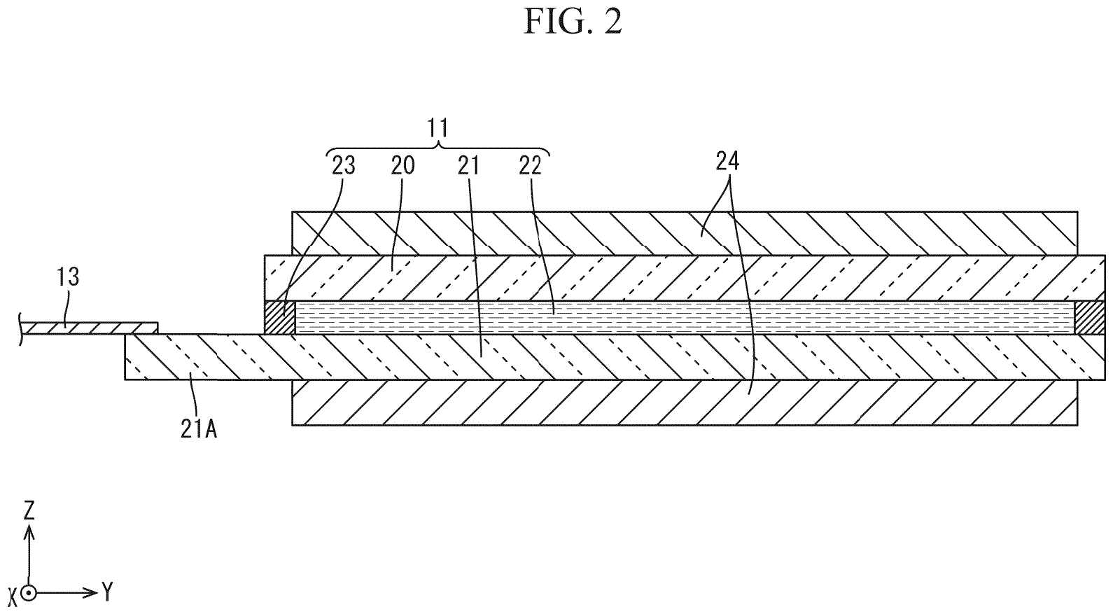

As illustrated in FIG. 2, the liquid crystal panel 11 includes a pair of substrates 20, 21 that are bonded to each other. At least a liquid crystal layer 22 and a sealing portion 23 for sealing the liquid crystal layer 22 are disposed between the substrates 20 and 21. The liquid crystal layer 22 includes liquid crystal molecules having optical characteristics that vary according to application of electric field. The sealing portion 23 is formed in a rectangular frame shape as a whole in a plan view and surrounds the liquid crystal layer 22 in the non-display area NAA. A gap corresponding to a thickness of the liquid crystal layer 22 can be maintained by the sealing portion 23. Polarizing plates 24 are attached to outer surfaces of the substrates 20 and 21.

One of the substrates 20, 21 on the front side (a front surface side) is an opposed substrate 20 (a CF substrate) and another one on the back side (a back surface side) is an array substrate 21 (an active matrix substrate, a TFT substrate). The opposed substrate 20 and the array substrate 21 include glass substrates that are almost transparent and have good light transmissive properties and various kinds of films that are formed in layers on an inner surface side the glass substrates.

A backlight unit that supplies light to the liquid crystal panel 11 is disposed behind the liquid crystal panel 11 (opposite the array substrate 21). The liquid crystal panel 11 of this embodiment is used for a head-mount display, for example, and has quite high definition. The pixel density of the liquid crystal panel 11 is from 800 ppi to 1800 ppi, for example.

The array substrate 21 is larger in size than the opposed substrate 20 and a portion of the array substrate 21 projects from an edge of the opposed substrate 20. A flexible substrate 13 includes a base having insulating properties and flexibility and multiple traces formed on the base. A first end of the flexible substrate 13 is connected to the array substrate 21 and a second end of the flexible substrate 13 is connected to an external control board (a signal supply). Various kinds of signals supplied from the control board are transmitted to the liquid crystal panel 11 via the flexible substrate 13.

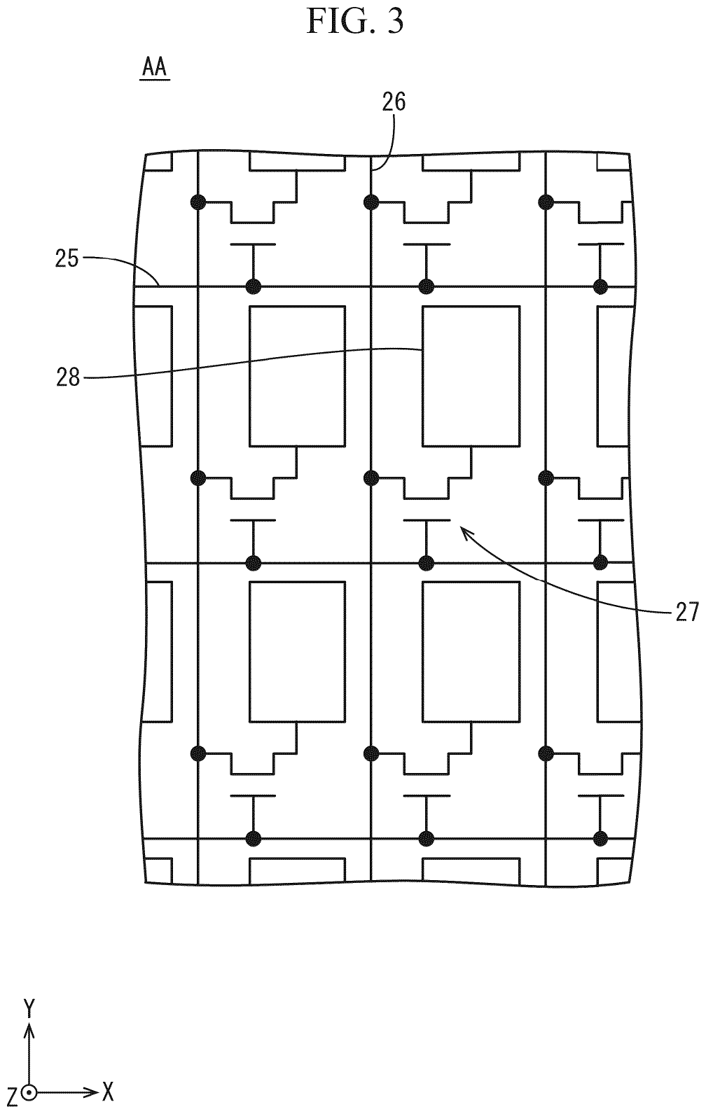

As illustrated in FIG. 3, gate lines 25 (scan lines) and source lines 26 (image lines) are arranged in a grid in the display area AA of the array substrate 21. The gate lines 25 extend in a direction substantially along the X-axis direction and cross laterally the display area AA. The gate lines 25 are arranged at intervals in the Y-axis direction. The gate lines 25 are supplied with scan signals output from a first circuit 14A sequentially from the upper one in FIG. 3. The source lines 26 extend in a direction substantially along the Y-axis direction to cross vertically the display area AA. The source lines 26 cross the gate lines 25. The source lines 26 are arranged at intervals in the X-axis direction. The source lines 26 are supplied with image signals output from a second circuit 14B.

A first TFT 27 and a pixel electrode 28 are disposed near a crossing portion of the gate line 25 and the source line 26. The first TFTs 27 and the pixel electrodes 28 are arranged regularly along the X-axis direction and the Y-axis direction. The first TFT 27 is connected to the gate line 25, the source lin26, and the pixel electrode 28. With the first TFT 27 being driven based on the scan signal supplied to the gate line 25, the pixel electrode 28 is charged at the potential related to the image signal supplied to the source line 26.

As illustrated in FIG. 1, circuits 14 (a surrounding circuit) are disposed in the non-display area NAA of the array substrate 21. The circuits 14 include the first circuits 14A and a second circuit 14B. Two first circuits 14A are disposed to sandwich the display area AA with respect to the X-axis direction; however, the first circuit 14A may be disposed on only one side.

The first circuit 14A is disposed in a belt shape area extending in the Y-axis direction. The first circuits 14A are for supplying scan signals to the gate lines 25 and are monolithically fabricated on the array substrate 21. The first circuit 14A is a gate driver monolithic (GDM) circuit. The first circuit 14A includes a shift resister circuit that is configured to output the scan signal at a predetermined timing and a buffer circuit that is configured to amplify the scan signal.

The second circuit 14B is disposed between the display area AA and the flexible substrate 13 in the Y-axis direction. The second circuit 14B is disposed in a belt shape area extending in the X-axis direction. The second circuit 14B is for supplying image signals (data signals) to the source lines 26 and are monolithically fabricated on the array substrate 21. The second circuit 14B includes a demultiplexer circuit (a source signal distribution circuit). The second circuit 14B includes a switching function for distributing the image signals (source signals), which are supplied from a source driver 14C, to the source lines 26. The first circuits 14A and the second circuit 14B of the circuit 14 include various types of circuit components and at least include a second TFT 15.

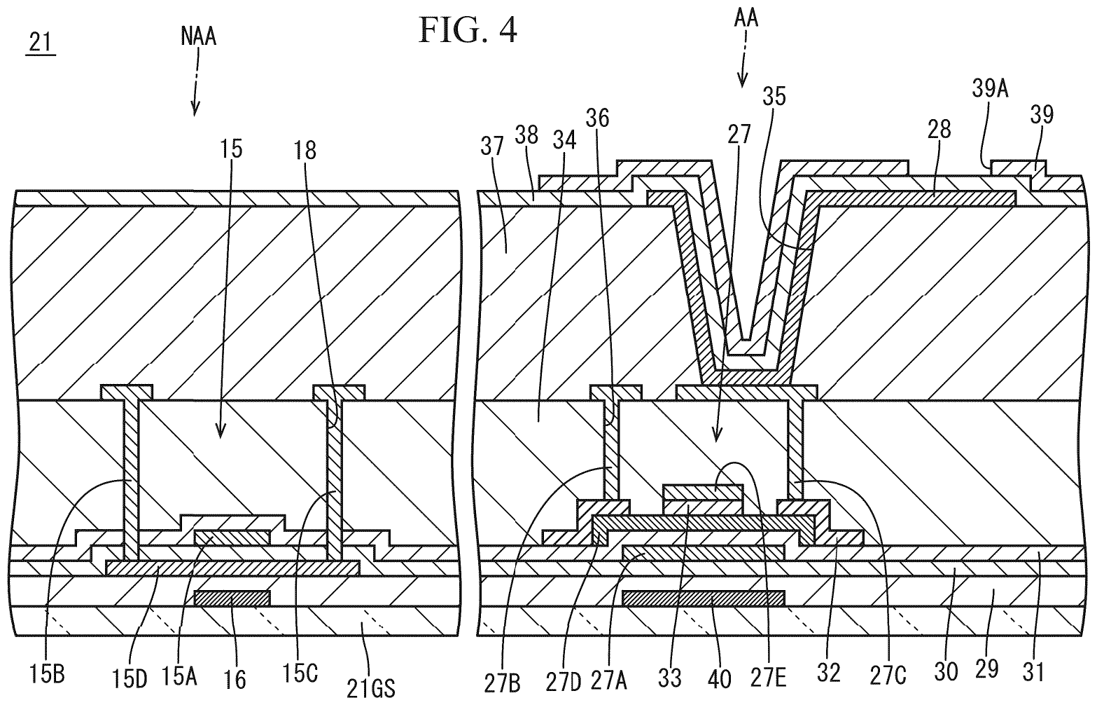

Next, a cross-sectional configuration of the array substrate 21 will be described in detail. FIG. 4 illustrates a cross-sectional configuration of the display area AA (the first TFT 27) and a cross-sectional configuration of the circuit 14 (the second TFT 15) in the non-display area NAA. As illustrated in FIG. 4, the first TFT 27 is arranged in the display area AA of the array substrate 21. The first TFT 27 includes a first gate electrode 27E, a second gate electrode 27A, a first source electrode 27B, a first drain electrode 27C, and a first semiconductor film 27D. The first semiconductor film 27D is included in a layer upper than a layer including the second gate electrode 27A and lower than a layer including the first source electrode 27B, the first drain electrode 27C, and the first gate electrode 27E. Therefore, the first semiconductor film 27D is sandwiched by the two gate electrodes 27A, 27E with respect to an upper-bottom direction and the first TFT 27 has a double gate structure. With the double gate structure, the first semiconductor film 27D can stably include a channel section.

As illustrated in FIG. 4, the second TFT 15 is arranged in the non-display area NAA of the array substrate 21. The second TFT 15 includes a third gate electrode 15A, a second source electrode 15B, a second drain electrode 15C, and a second semiconductor film 15D. The second semiconductor film 15D is included in a lowest layer with respect to a layer including the third gate electrode 15A, the second source electrode 15B, and the second drain electrode 15C. Therefore, the second TFT 15 has a top gate structure.

The array substrate 21 includes the above-described two types of TFTs 15, 27 and includes a substantially transparent glass substrate 21GS (one example of an insulating substrate) and various films formed in layers on the glass substrate 21GS. The glass substrate 21GS includes alkali-free glass as main material. On the glass substrate 21GS of the array substrate 21, the following films are at least disposed on top of each other in the following order from the lowest layer (the grass substrate GS side): a light blocking film portions of which are configured as a first light blocking portion 40 and a second light blocking portion 16, a basecoat film 29, a second semiconductor film 15D, a gate insulation film 30, a first metal film portions of which are configured as the third gate electrode 15A and the second gate electrode 27A, a first insulation film 31, the first semiconductor film 27D, a first transparent conductive film a portion of which is configured as an auxiliary film 32, a second insulation film 33, a second metal film a portion of which is configured as the first gate electrode 27E, a third insulation film 34, a third metal film portions of which are configured as the first source electrode 27B, the first drain electrode 27C, the second source electrode 15B, and the second drain electrode 15C, a planarization film 37, a second transparent conductive film portions of which are configured as the pixel electrodes 28, a fourth insulation film 38, and a third transparent conductive film a portion of which is configured as a common electrode 39. An alignment film is disposed in an uppermost layer of the array substrate 21 (a layer closest to the liquid crystal layer 22) to cover the above-described films.

Each of the light blocking film, the first metal film, the second metal film, and the third metal film is a single-layer film made of one kind of metal, a multilayer film made of different kinds of metals, or alloy, and has electrically conductive properties and light blocking properties.

The first transparent conductive film, the second transparent conductive film, and the third transparent conductive film are made of transparent conductive material such as indium tin oxide (ITO) and indium zinc oxide (IZO).

Each of the basecoat film 29, the gate insulation film 30, the first insulation film 31, the second insulation film 33, the third insulation film 34, and the fourth insulation film 38 is made of inorganic material (inorganic resin material) and may be a single-layer film or a multilayer film including SiOₓ (silicon oxide) and SiNₓ (silicon nitride). The thickness of the gate insulation film 30 and the second insulation film 33 is from about 80 nm to 120 nm. The second insulation film 33 is configured as a gate insulation film of the first gate electrode 27E, which is a portion of the second metal film. The second insulation film 33 has a planar size so as to overlap the first gate electrode 27E. The thickness of the first insulation film 31 is greater than that of the gate insulation film 30 and is about 300 nm. The thickness of the third insulation film 34 is about from 500 nm to 700 nm.

The planarization film 37 is made of organic material (organic resin material) such as PMMA (acrylic resin). The planarization film 37 normally has a film thickness greater than that of other insulation films made of inorganic material.

The first semiconductor film 27D is made of oxide semiconductor material. The oxide semiconductor material has higher resistance value with no voltage being applied (OFF state) compared to polysilicon semiconductor material. The oxide semiconductor material has higher electron mobility than the amorphous silicon semiconductor material.

Oxide semiconductor material that includes at least one kind of metallic elements out of In, Ga, and Zn may be used as the oxide semiconductor material. The oxide semiconductor material may be amorphous or crystalline and may be an In—Ga—Zn—O semiconductor (for example, In—Ga—Zn oxide). Examples of the oxide semiconductor material may include an In—Sn—Zn—O semiconductor (for example, In₂O₃—SnO₂—ZnO; InSnZnO), an In—W—Zn—O semiconductor, an In—W—Sn—Zn—O semiconductor, an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, a Cd—Pb—O semiconductor, cadmium oxide (CdO), a Mg—Zn—O semiconductor, an In—Ga—Sn—O semiconductor, an In—Ga—O semiconductor, a Zr—In—Zn—O semiconductor, a Hf—In—Zn—O semiconductor, an Al—Ga—Zn—O semiconductor, a Ga—Zn—O semiconductor, and an In—Ga—Zn—Sn—O semiconductor.

The second gate electrode 27A is a portion of the first metal film. The second gate electrode 27A is disposed to overlap the first semiconductor film 27D via the first insulation film 31 and in a layer lower than the layer including the first semiconductor film 27D. The second gate electrode 27A is disposed to overlap a middle portion of the first semiconductor film 27D.

The first gate electrode 27E is a portion of the second metal film. The first gate electrode 27E is disposed to overlap the first semiconductor film 27D via the second insulation film 33 and in a layer upper than the layer including the first semiconductor film 27D. The first gate electrode 27E is disposed to overlap a middle portion of the first semiconductor film 27D. The first gate electrode 27E has a planar size smaller than that of the second gate electrode 27A and is disposed to overlap a middle portion of the second gate electrode 27A.

The first gate electrode 27E is connected to the second gate electrode 27A. At least one of the first gate electrode 27E and the second gate electrode 27A is connected to the gate line 25 (refer to FIG. 3). Therefore, the scan signals supplied to the gate line 25 is supplied to the gate electrodes 27A, 27E and the gate electrodes 27A, 27E have a same potential. With the scan signals being supplied to the gate electrodes 27A, 27E, the channel section is created in the first semiconductor film 27D.

The first source electrode 27B and the first drain electrode 27C are portions of the third metal film. The first source electrode 27B overlaps a first end portion of the first semiconductor film 27D and the first drain electrode 27C overlaps a second end portion of the first semiconductor film 27D. The first source electrode 27B is continuous to the source line 26 (refer to FIG. 3).

Upper portions of the first source electrode 27B and the first drain electrode 27C are disposed in a layer upper than the layer including the first semiconductor film 27D via the third insulation film 34. The third insulation film 34 includes first contact holes 36. The first contact hole 36 is formed in a portion of the third insulation film 34 where each of the first source electrode 27B and the first drain electrode 27C overlaps the first semiconductor film 27D and does not overlap the first gate electrode 27E. The first source electrode 27B and the first drain electrode 27C are connected to the auxiliary film 32 via the first contact holes 36 (with being inserted in the first contact holes 36) and are connected to the first semiconductor film 27D via the auxiliary film 32.

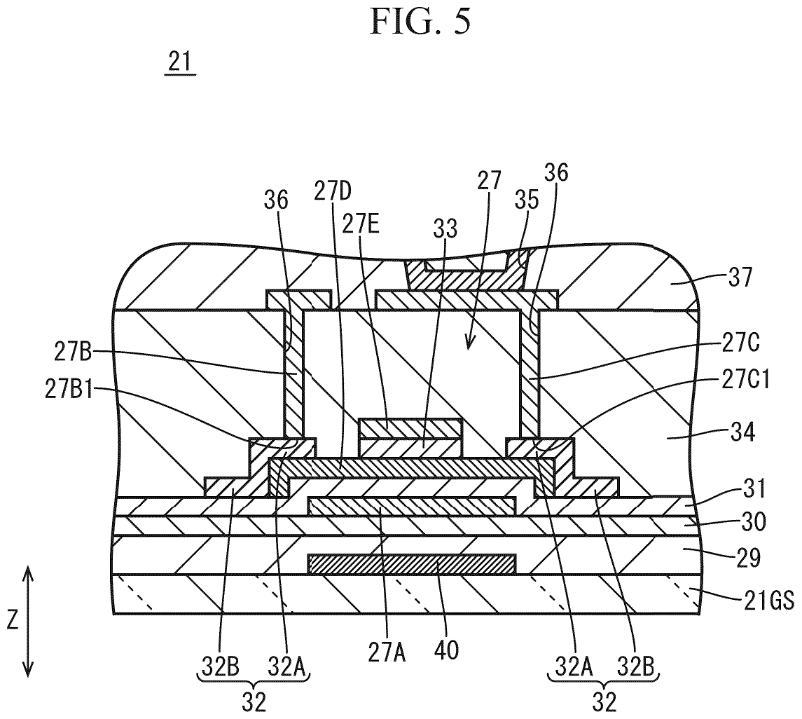

The auxiliary film 32 is a portion of the first transparent electrode film. As illustrated in FIG. 5, the auxiliary film 32 is disposed between a lower surface 27B1 of the first source electrode 27B and the first semiconductor film 27D and between a lower surface 27C1 of the first drain electrode 27C and the first semiconductor film 27D. Therefore, the auxiliary film 32 is disposed to overlap the lower surface 27B1 of the first source electrode 27B and the lower surface 27C1 of the first drain electrode 27C and not to overlap the first gate electrode 27E and the second insulation film 33. The auxiliary film 32 of this embodiment is configured as a stopper film. Since this embodiment includes the auxiliary film 32, the first semiconductor film 27D that is included in a layer lower than the layer including the first contact holes 36 is less likely to be etched (over-etching) when the first contact holes 36 are formed with etching.

The auxiliary film 32 of this embodiment includes a protection portion 32A and an extending portion 32B. The protection portion 32A overlaps the lower surface 27B1 of the first source electrode 27B and the lower surface 27C1 of the first drain electrode 27C and is disposed between the first semiconductor film 27D and each of the lower surfaces 27B1, 27C1 to protect the first semiconductor film 27D. The extending portion 32B extends from the protection portion 32A to be away from the first gate electrode 27E. The extending portion 32B is configured as a margin with which the variation in the planar pattern and position displacement of the planar patterns of the components can be adjusted. With the extending portion 32B being provided, the first contact holes 36 can be appropriately formed corresponding to the first semiconductor film 27D even with the position displacement from the first semiconductor film 27D.

The pixel electrode 28 is a portion of the second transparent conductive film. An upper portion of the pixel electrode 28 is disposed to overlap the first drain electrode 27C. The planarization film 37 that is disposed between the pixel electrode 28 and the first drain electrode 27C includes a contact hole 35. The pixel electrode 28 is connected to the first drain electrode 27C via the contact hole 35.

The common electrode 39 is a portion of the third transparent conductive film. The common electrode 39 is formed to overlap all the pixel electrodes 28 via the fourth insulation film 38. The common electrode 39 is included in a layer upper than the layer including the pixel electrodes 28. The common electrode 39 includes slits 39A in portions overlapping the pixel electrodes 28. The common electrode 39 is supplied with a common potential signal of a common potential (a reference potential). With the pixel electrode 28 being charged with a potential based on the image signal transmitted to the source line 26 according to the driving of the first TFT 27, a potential difference occurs between the pixel electrode 28 and the common electrode 39. Then, a fringe electric field (an oblique electric field) is created between an opening edge of the slit 39A of the common electrode 39 and the pixel electrode 28. The fringe electric field includes a component parallel to the plate surface of the array substrate 21 and a component normal to the plate surface of the array substrate 21. With the fringe electric field, orientations of the liquid crystal molecules included in the liquid crystal layer 22 can be controlled. Namely, the liquid crystal panel 11 according to this embodiment operates in the fringe field switching (FFS) mode.

In the display area AA, the first light blocking portion 40 is disposed to overlap at least an entire area of the first gate electrode 27E. The first light blocking portion 40 is a portion of a light blocking film that is disposed in a lowest layer in the array substrate 21. The first light blocking portion 40 is disposed to overlap a most portion of the second gate electrode 27A. The first light blocking portion 40 is disposed to overlap the channel section of the first semiconductor film 27D created by the application of voltage to the first gate electrode 27E and the second gate electrode 27A. The first light blocking portion 40 is included in a layer lower than the layer including the channel section. With such a configuration, the light supplied from the backlight unit to the channel section of the first semiconductor film 27D from the lower layer side can be blocked by the first light blocking portion 40. As a result, the characteristics of the first TFTs 27 are less likely to change due to the supply of the light to the channel section of the first semiconductor film 27D.

Next, a cross-sectional configuration of the second TFT 15 of the circuit 14 will be described with reference to FIG. 4. As previously described, the second TFT 15 includes the third gate electrode 15A, the second source electrode 15B, the second drain electrode 15C, and the second semiconductor film 15D. The second semiconductor film 15D is included in a lowest layer among the layers including the electrodes 15A, 15B, 15C. The second semiconductor film 15D is made of polysilicon semiconductor material that has crystalline structure created with a known method such as laser crystallization. The polysilicon semiconductor material has electron mobility higher than that of oxide semiconductor material.

A portion of the first metal film is configured as the third gate electrode 15A and is different from the portion of the first metal film that is configured as the second gate electrode 27A. The third gate electrode 15A of the second TFT 15 and the second gate electrode 27A of the first TFT 27 are portions of the first metal film. Therefore, compared to a configuration including two metal films one of which is for the third gate electrode 15A and other one of which is for the second gate electrode 27A, the number of metal films can be reduced. The third gate electrode 15A is included in a layer upper than the layer including the second semiconductor film 15D via the gate insulation film 30. The third gate electrode 15A is disposed to overlap a middle portion of the second semiconductor film 15D.

Portions of the third metal film are configured as the second source electrode 15B and the second drain electrode 15C and differ from the portions of the third metal film that are configured as the first source electrode 27B and the first drain electrode 27C. The second source electrode 15B and the second drain electrode 15C of the second TFT 15 and the first source electrode 27B and the first drain electrode 27C of the first TFT 27 are portions of the third metal film. Therefore, compared to a configuration including two metal films one of which is for the electrodes 15B, 15C of the second TFT 15 and other one of which is for the electrodes 27B, 27C of the first TFT 27, the number of metal films can be reduced. The second source electrode 15B overlaps a first end portion of the second semiconductor film 15D and the second drain electrode 15C overlaps a second end portion of the second semiconductor film 15D.

Portions of the second source electrode 15B and the second drain electrode 15C are included in a layer upper than the layer including the second semiconductor film 15D via the gate insulation film 30, the first insulation film 31, and the third insulation film 34. The gate insulation film 30, the first insulation film 31, and the third insulation film 34 include second contact holes 18. The second contact hole 18 is in a portion of each of the insulation films where each of the second source electrode 15B and the second drain electrode 15C overlaps the second semiconductor film 15D and does not overlap the third gate electrode 15A. The second source electrode 15B and the second drain electrode 15C are connected to the second semiconductor film 15D via the second contact holes 18 (with being inserted in the second contact holes 18).

The second light blocking portion 16 is disposed to overlap at least the third gate electrode 15A. The second light blocking portion 16 is a portion of the light blocking portion that includes a portion configured as the first light blocking portion 40. The second light blocking portion 16 is disposed to overlap the channel section of the second semiconductor film 15D that is created by the application of voltage to the third gate electrode 15A. The second light blocking portion 16 is included in a layer lower than the layer including the channel section. With such a configuration, the light supplied from the backlight unit to the channel section of the second semiconductor film 15D from the lower layer side can be blocked by the second light blocking portion 16. As a result, the characteristics of the second TFTs 15 are less likely to change due to the supply of the light to the channel section of the second semiconductor film 15D.

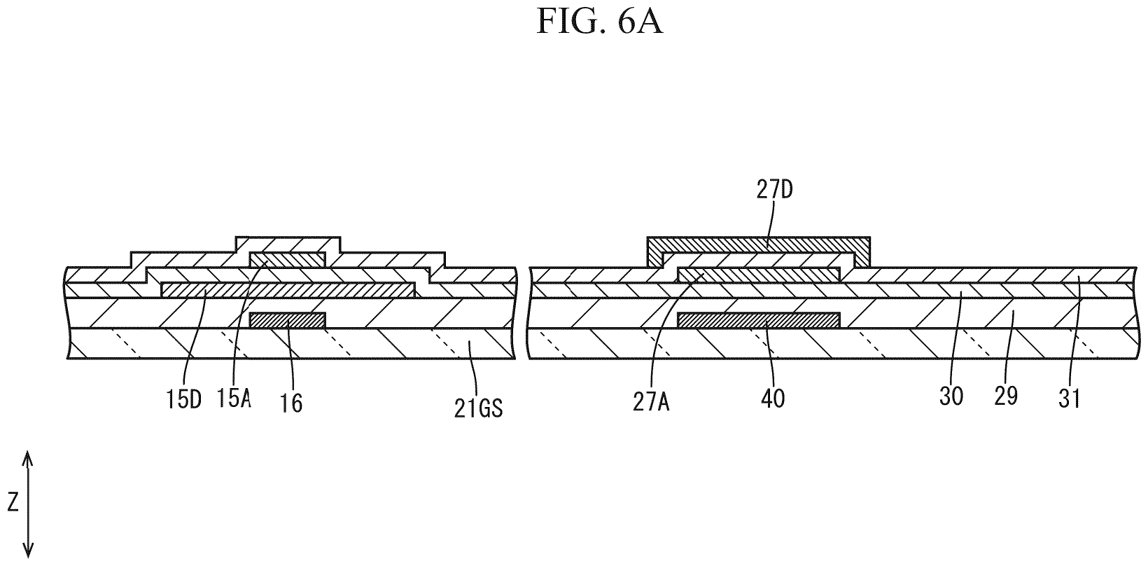

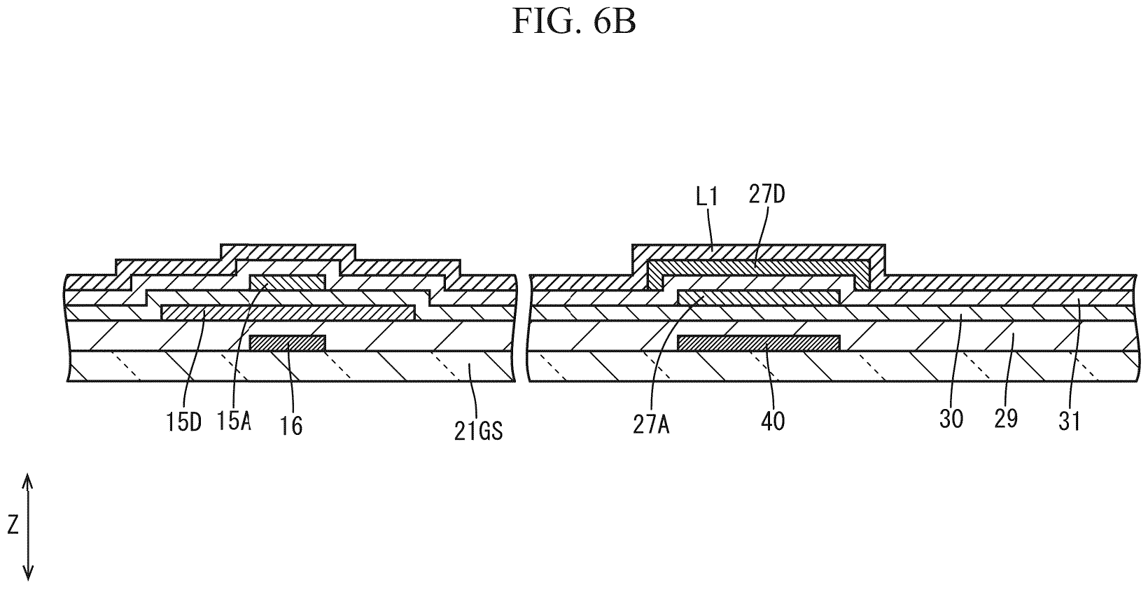

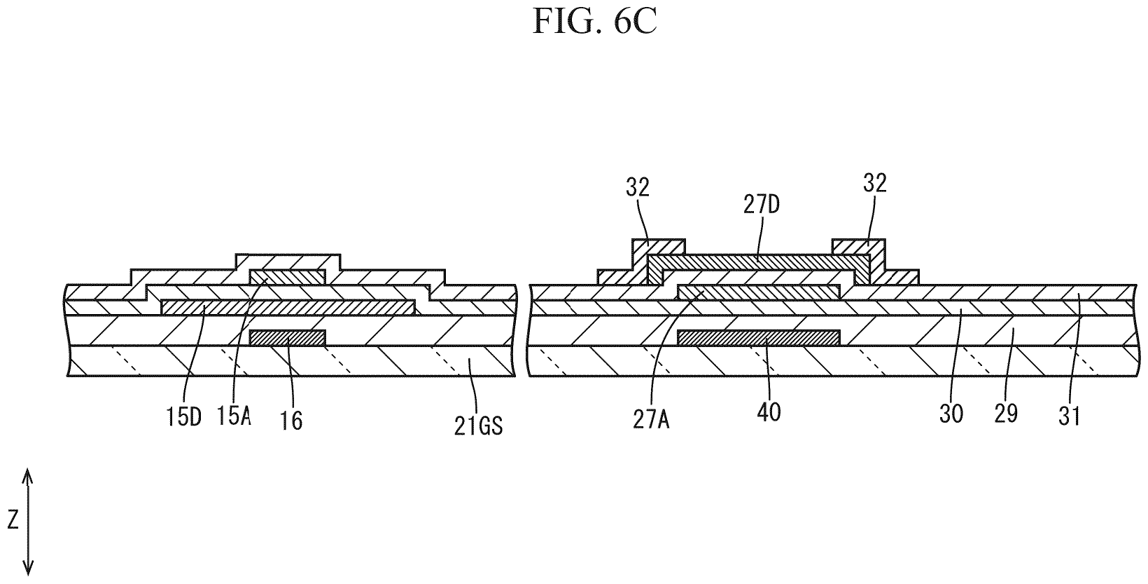

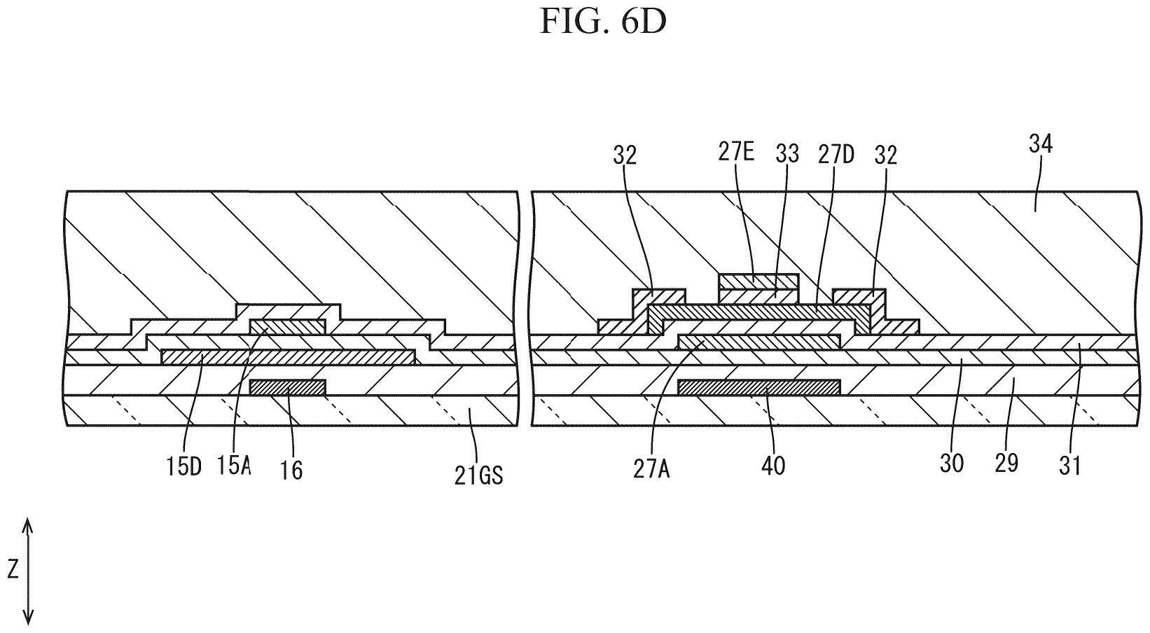

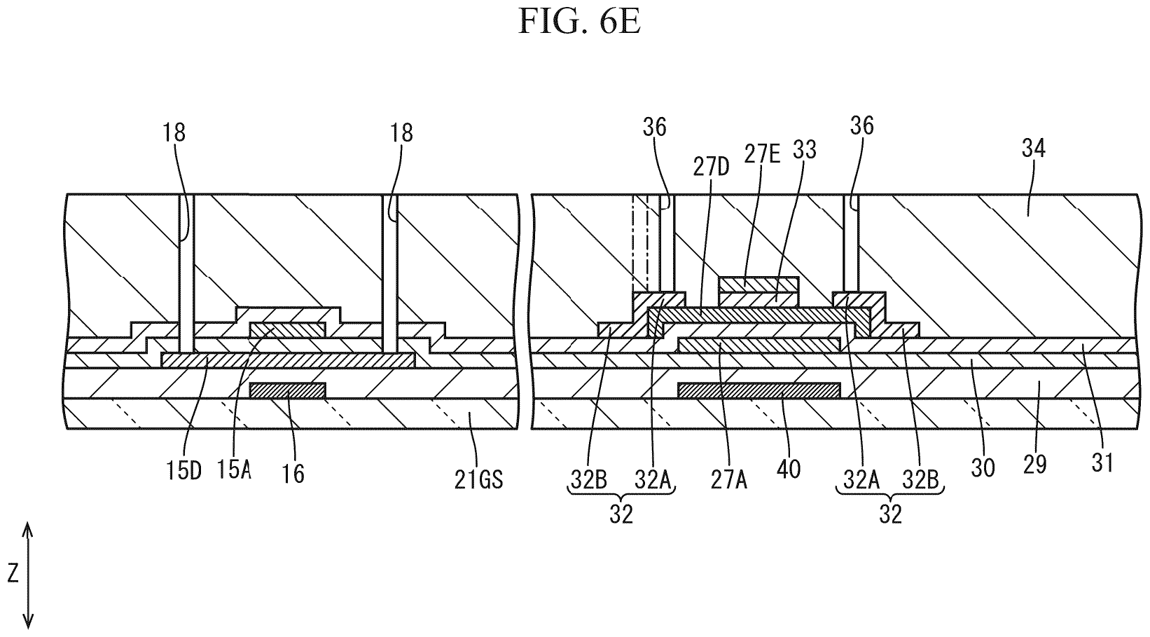

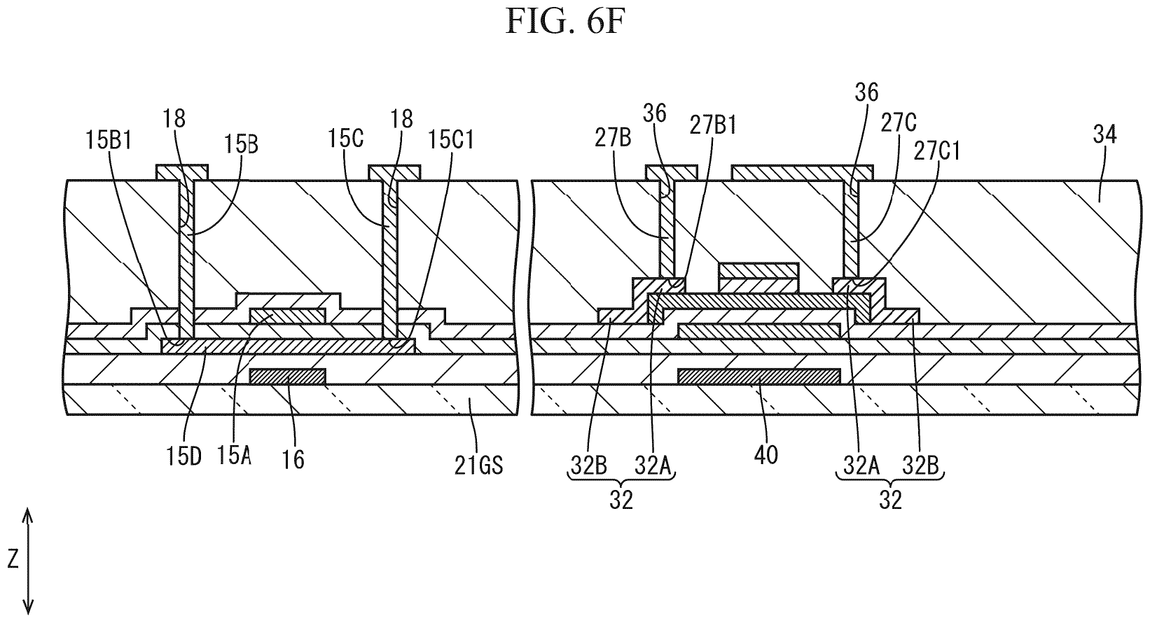

Next, a method of producing the array substrate 21 will be described. A producing process of the layered structure of FIG. 4 will be described. The producing process after forming of the first insulation film 31 and before forming of the planarization film 37 will be described with reference to FIGS. 6A to 6F.

The first semiconductor film 27D is disposed on the first insulation film 31 with patterning (FIG. 6A) and a transparent conductive film L1 made of transparent conductive material is formed on the first semiconductor film 27D (FIG. 6B). The transparent conductive film L1 is subjected to patterning to form the auxiliary film 32 (FIG. 6C). Next, the second insulation film 33 and the first gate electrode 27E are formed with patterning on the first semiconductor film 27D and thereafter, the third insulation film 34 is formed (FIG. 6D).

In this embodiment, with patterning, a film is processed with a general photolithography method. Specifically, with patterning, the following steps are performed. A photoresist film is formed on a film to be processed, the photoresist film is exposed with an exposure device via a photomask having a predefined pattern and developing the photoresist film, and the film to be processed is subjected to etching via the developed photoresist film.

Next, the first contact holes 36 and the second contact holes 18 are formed in the same process (FIG. 6E). The first contact holes 36 are formed by etching the third insulation film 34 with patterning and the auxiliary film 32 functions as the stopper film when the etching is performed. The second contact holes 18 are formed by etching sequentially the third insulation film 34, the first insulation film 31, and the gate insulation film 30 from the upper layer side with patterning and the second semiconductor film 15D functions as the stopper film when the etching is performed.

After forming the first contact holes 36 and the second contact holes 18, the first source electrode 27B, the first drain electrode 27C, the second source electrode 15B, and the second drain electrode 15C are formed with patterning (FIG. 6F). Accordingly, the first contact holes 36 are filled with the first source electrode 27B and the first drain electrode 27C, respectively, and the second contact holes 18 are filled with the second source electrode 15B and the second drain electrode 15C, respectively. The lower surface 27B1 of the first source electrode 27B and the lower surface 27C1 of the first drain electrode 27C are contacted with and connected to upper surfaces of the protection portions 32A of the auxiliary film 32. As a result, the first source electrode 27B and the first drain electrode 27C are connected to the first semiconductor film 27D via the auxiliary film 32. On the other hand, the lower surface 15B1 of the second source electrode 15B and the lower surface 15C1 of the second drain electrode 15C are contacted with an upper surface of the second semiconductor film 15D and directly connected to the second semiconductor film 15D.

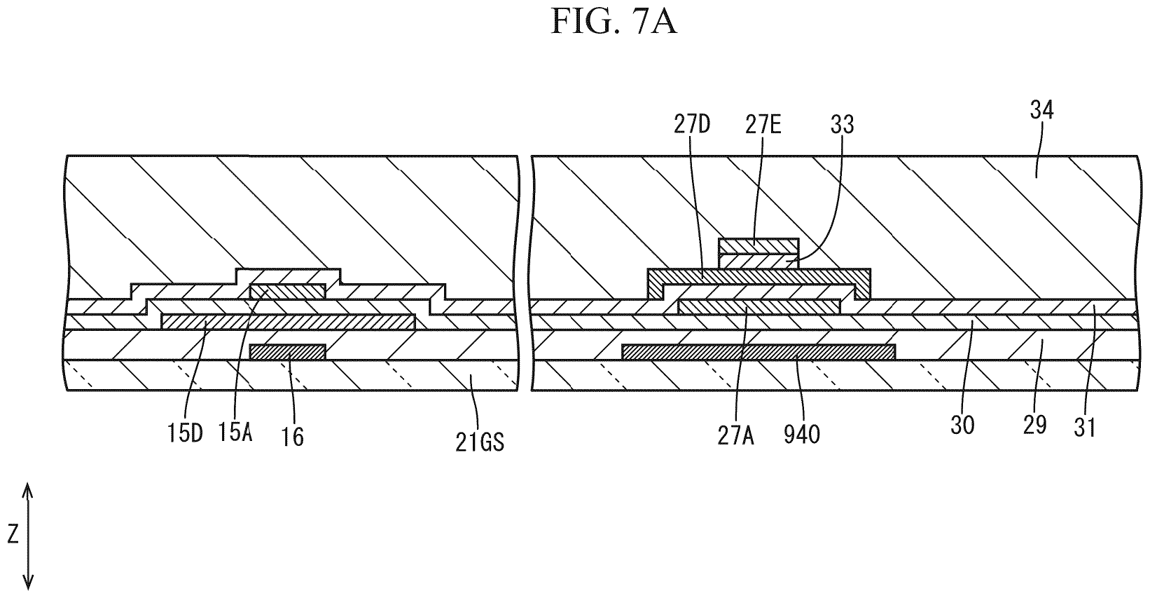

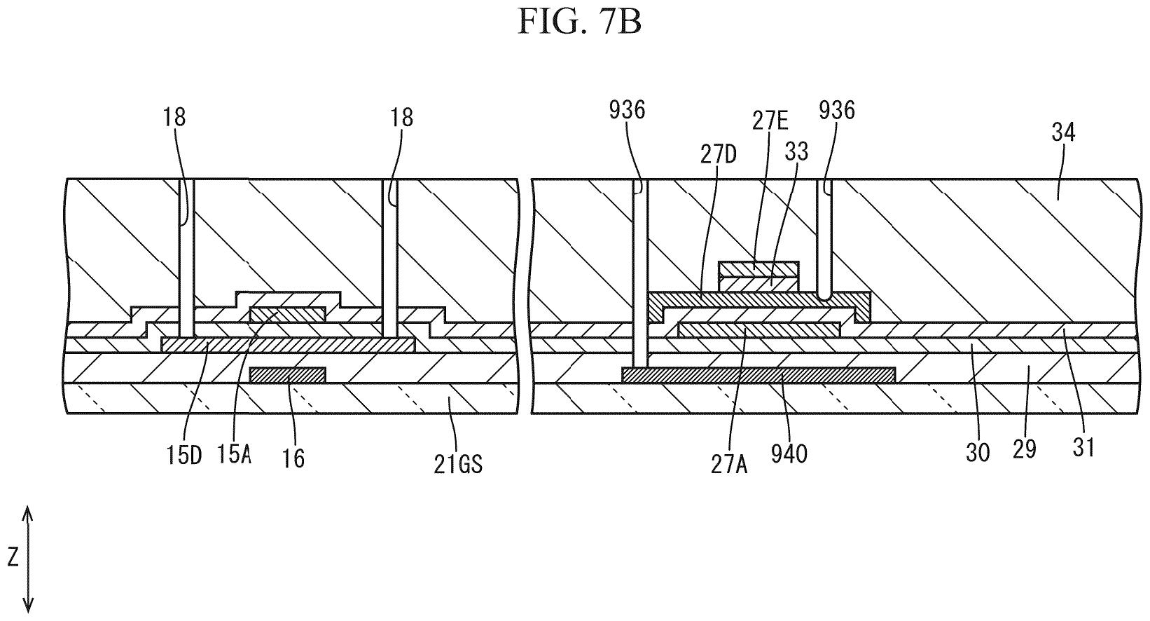

In the contact hole forming process (FIG. 6E), the first contact hole 36 and the second contact hole 18 are formed in the same process; however, the first contact hole 36 and the second contact hole 18 have different lengths (depths). Therefore, the first contact hole 36 that is shorter than the second contact hole 18 may be over-etched and the lower layer is likely to be corroded with corrosive agent. More specifically, without the auxiliary film 32, the first semiconductor film 27D may be corroded and the thickness thereof may be excessively decreased like Comparative Example 1 illustrated in FIGS. 7A and 7B. As illustrated in FIG. 7B, a first contact hole 936 may extend through the first semiconductor film 27D due to the etching time and position displacement of the photomask.

In this embodiment, as illustrated in FIG. 5, the auxiliary film 32 is disposed on the first semiconductor film 27D and the first semiconductor film 27D is protected by the protection portion 32A of the auxiliary film 32. With such a configuration, due to the over-etching for forming the first contact hole 36, the thickness of the first semiconductor film 27D is less likely to be excessively decreased and the first contact hole 36 is less likely to extend through the first semiconductor film 27D. According to this embodiment, the first contact hole 36 and the second contact hole 18 can be formed appropriately in the same process. Therefore, compared to the method in which the first contact hole 36 and the second contact hole 18 are formed in different processes, the number of times of patterning (etching) the insulation film (the third insulation film 34, the first insulation film 31, and the gate insulation film 30) can be reduced and the manufacturing process can be shortened.

The auxiliary film 32 is a portion of the first transparent conductive film and does not have light blocking properties. Therefore, even if the auxiliary film 32 has a large plan view size with considering the manufacturing variation, the opening ratio is less likely to be reduced due to the auxiliary film 32. With the auxiliary film 32, the first semiconductor film 27D of the first TFT 27 can be protected without reducing the opening ratio.

With the extending portion 32B of the auxiliary film 32 being provided, the first contact holes 36 can be appropriately formed even with the position displacement from the first semiconductor film 27D. If the first contact hole 936 is formed in a position different from the correct position without the auxiliary film 32, like Comparative Example 1 illustrated in FIGS. 7A and 7B, the first contact hole 936 may extend through the first insulation film 31, the gate insulation film 30, and the basecoat film 29 that are in layers lower than the layer including the first semiconductor film 27D. Therefore, the planar size of a first light blocking portion 940 needs to be greater than that of the first semiconductor film 27D to protect the glass substrate 21GS from the over-etching for forming the first contact hole 936. This reduces the opening ratio due to the first light blocking portion 940 having a large planar size.

In this embodiment, even if the first contact hole is formed in a position that does not correspond to the first semiconductor film 27D as illustrated with a chain line in FIG. 6E, the over-etching for forming the contact hole is less likely to occur because the extending portion 32B of the auxiliary film 32 stops the over-etching. Therefore, the planar size of the first light blocking portion 40 need not be increased to be greater than that of the first semiconductor film 27D and the opening ratio is less likely to be reduced. The first light blocking portion 40 has a planar size such that the light supplied from the lower layer side to the channel section of the first semiconductor film 27D can be blocked (same as the planar size of the second gate electrode 27A, for example).

### Second Embodiment

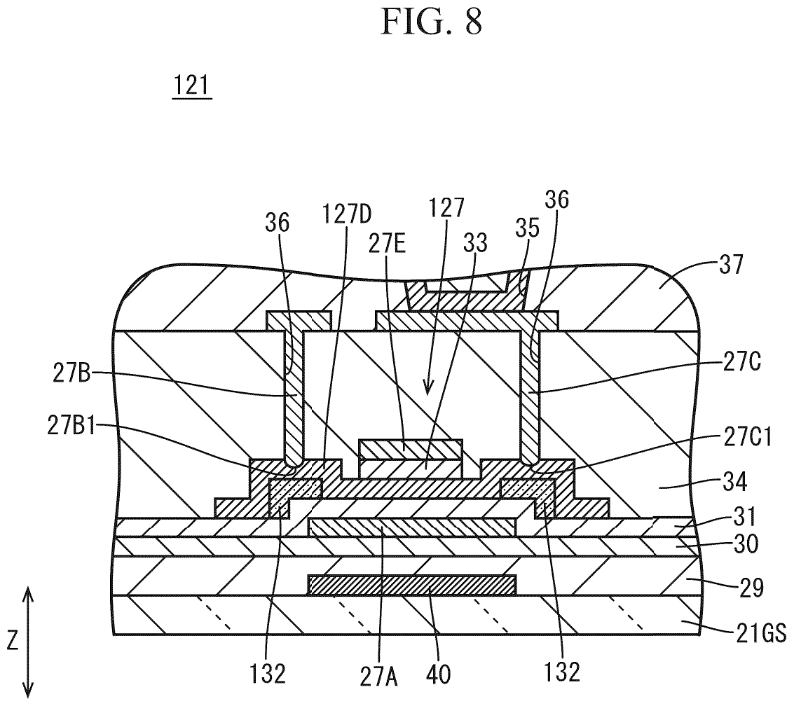

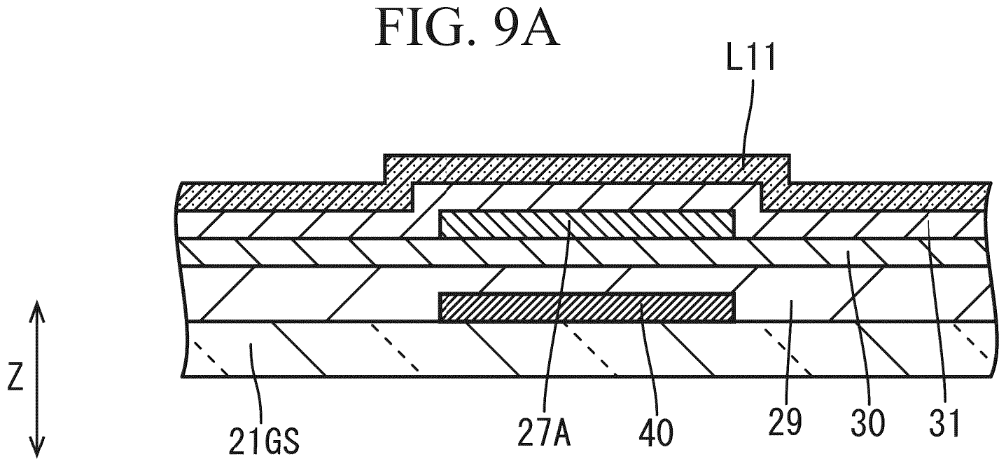

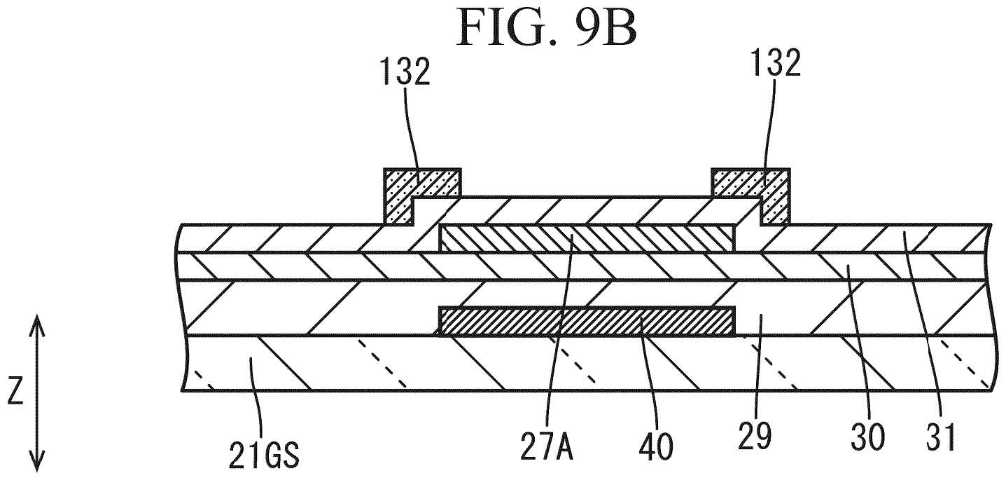

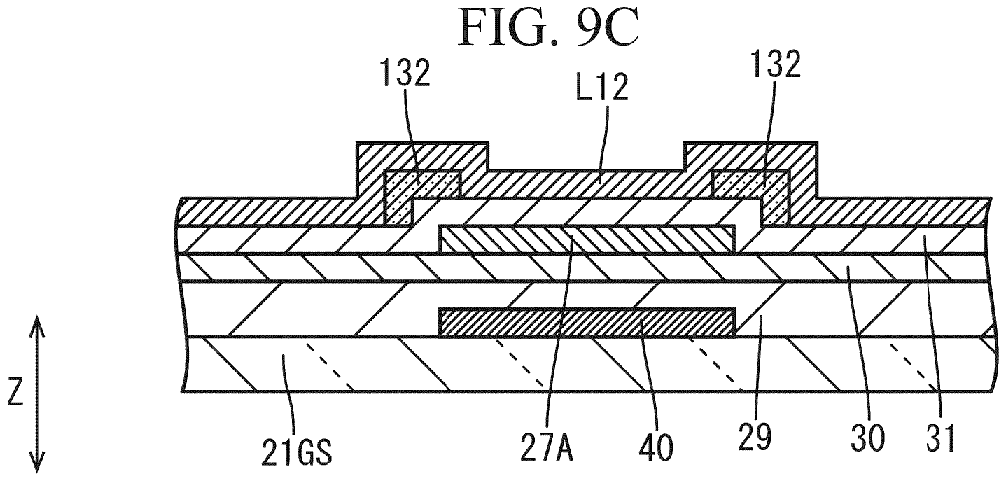

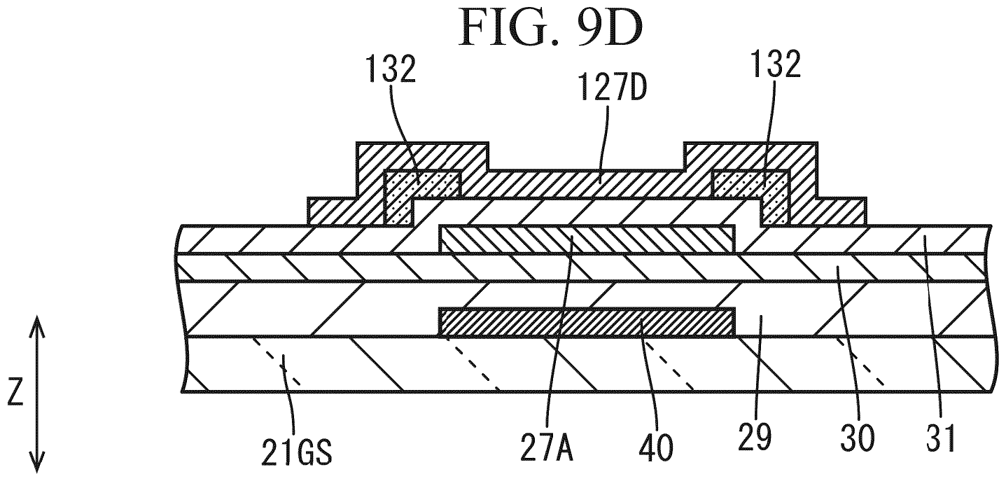

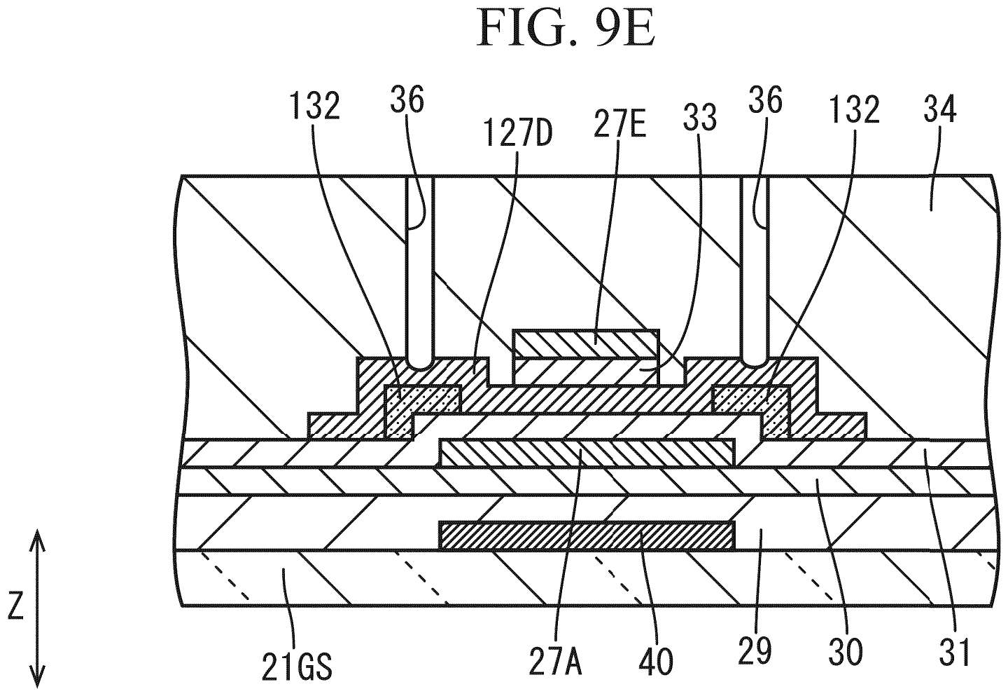

A first TFT 127 of an array substrate 121 according to a second embodiment will be described with reference to FIGS. 8 and 9A to 9E. The first TFT 127 of the second embodiment includes an auxiliary film 132 in a layer lower than the layer including a first semiconductor film 127D. The auxiliary film 132 is made of a same material as that of the first semiconductor film 127D. Components of the second embodiment same as those of the first embodiment are referred to with same reference numbers. Configurations, operations, and effects similar to those of the first embodiment may not be described.

The auxiliary film 132 is disposed in a layer lower than the layer including the first semiconductor film 127D and disposed to overlap each of the lower surface 27B1 of the first source electrode 27B and the lower surface 27C1 of the first drain electrode 27C. Since the auxiliary film 132 is made of the same material as that of the first semiconductor film 127D, the first semiconductor film 127D of this embodiment includes thick portions that overlap the auxiliary film 132.

With such a configuration, even if the thickness of the first semiconductor film 127D is reduced due to the over-etching for forming the first contact hole 36, the auxiliary film 132 can function as the first semiconductor film 127D.

Next, a method of producing the array substrate 121 will be described. A semiconductor film L11 made of semiconductor material is formed on the first insulation film 31 (FIG. 9A). The material of the semiconductor film L11 is same as that of the first semiconductor film 127D. The semiconductor film L11 is subjected to patterning to form the auxiliary film 132 (FIG. 9B). A semiconductor film L12 made of the semiconductor material is formed on the auxiliary film 132 (FIG. 9C). The semiconductor film L12 is subjected to patterning to form the first semiconductor film 127D (FIG. 9D). Next, the second insulation film 33 and the first gate electrode 27E are formed with patterning on the first semiconductor film 127D and thereafter, the third insulation film 34 is formed and the first contact holes 36 and the second contact holes 18 are formed in the same process (FIG. 9E).

The first contact holes 36 are formed by etching the first third insulation film 34 with patterning and the semiconductor film 127D functions as the stopper film when the etching is performed. Even if the thickness of the first semiconductor film 127D is reduced due to the over-etching for forming the first contact hole 36, the auxiliary film 132 can function as the first semiconductor film 127D. With the auxiliary film 132 being made of the same material as that of the first semiconductor film 127D, the characteristics of the first TFTs 127 are less likely to change due to the forming of the auxiliary film 132.

If the auxiliary film 132, which is made of the same material as that of the first semiconductor film 127D and included in the layer upper than the layer including the first semiconductor film 127D like the first embodiment, is etched with patterning, a portion of the first semiconductor film 127D that does not overlap the auxiliary film 132 is etched. In this respect, according to this embodiment, since the auxiliary film 132 is included in the layer lower than the layer including the first semiconductor film 127D, such a problem does not occur.

### Other Embodiments

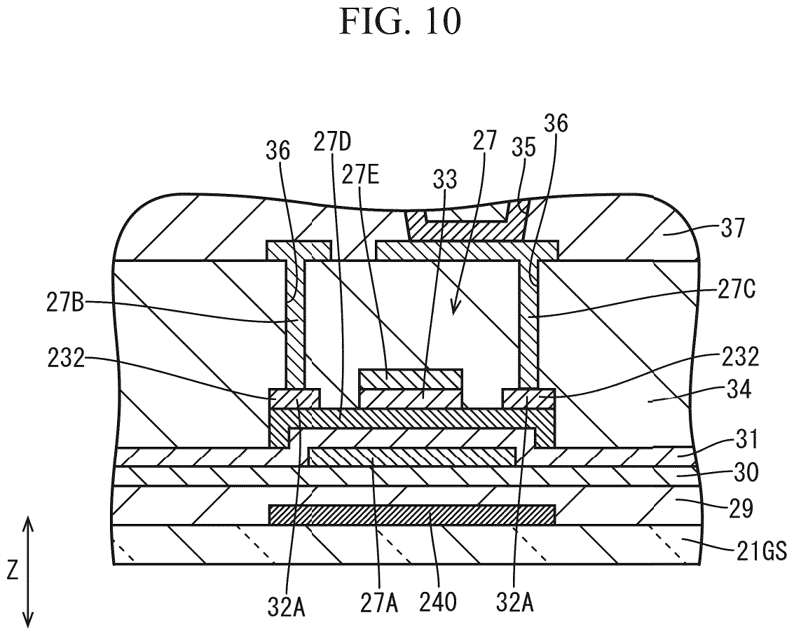

The technology described herein is not limited to the embodiments described above and illustrated by the drawings. For example, the following embodiments will be included in the technical scope of the present technology.
(1) The auxiliary film 32 of the first embodiment at least includes the protection portion 32A and may not include the extending portion 32B. Such a configuration of an auxiliary film 232 is illustrated in FIG. 10. In this configuration, a first light blocking portion 240 preferably has a large planar size. Accordingly, the characteristics of the first TFTs 27 are less likely to change due to the forming of the auxiliary film 232.
(2) The material of the auxiliary film 32, 232 of the first embodiment and the above (1) may not be necessarily transparent conductive material but may be semiconductor material that is different from the material of the first semiconductor film 27D.
(3) The array substrate 21, 121 may not necessarily have the layered structure and the layout pattern illustrated in the drawings. For example, the array substrate 21, 121 may include lines for a touch panel function.
(4) The display mode of the liquid crystal panel 11 may not be the FFS mode but may be other modes such as the IPS (in plane switching) mode. The common electrode 39 may be included in the opposed substrate 20 according to the display mode.
(5) The present technology may be applied to different types of display panels such as organic electro luminescence display panels.

1. An array substrate comprising:
an insulating substrate; and
a first TFT including
a first insulation film disposed on an upper layer side of the insulating substrate;
a first semiconductor film disposed in a layer upper than a layer including the first insulation film;
a second insulation film disposed in a layer upper than the layer including the first semiconductor film;
a first gate electrode disposed in a layer upper than the layer including the second insulation film and overlapping the first semiconductor film;
a third insulation film disposed in a layer upper than the layer including the first gate electrode;
a first source electrode and a first drain electrode that are portions of a metal film that is disposed in a layer upper than the layer including the third insulation film, the first source electrode and the first drain electrode being connected to the first semiconductor film via first contact holes that are through the third insulation film; and
an auxiliary film made of non-metal material and disposed in a layer upper or lower than the layer including the first semiconductor film to overlap at least lower surfaces of the first source electrode and the first drain electrode.

2. The array substrate according to claim 1, wherein the auxiliary film is included in the layer upper than the layer including the first semiconductor film and made of transparent conductive material.

3. The array substrate according to claim 1, wherein the auxiliary film is included in the layer lower than the layer including the first semiconductor film and made of material same as that of the first semiconductor film.

4. The array substrate according to claim 1, further comprising a first light blocking portion disposed in a layer lower than the layer including the first insulation film, the first light blocking portion overlapping the first gate electrode and not overlapping the lower surfaces of the first source electrode and the first drain electrode.

5. The array substrate according to claim 1, wherein the first TFT further includes a second gate electrode disposed in a layer lower than the layer including the first insulation film and the first TFT has a double gate structure.

6. The array substrate according to claim 5, further comprising a second TFT that includes:
a second semiconductor film;
a gate insulation film disposed in a layer upper than a layer including the second semiconductor film;
a third gate electrode disposed in a layer upper than the layer including the gate insulation film and made of same material as material of the second gate electrode;
the first insulation film disposed in the layer upper than the layer including the third gate electrode;
the third insulation film disposed in the layer upper than the first insulation film; and
a second source electrode and a second drain electrode connected to the second semiconductor film via second contact holes that are through the third insulation film, the first insulation film, and the gate insulation film, wherein
the first semiconductor film of the first TFT is made of oxide semiconductor material, and
the second semiconductor film of the second TFT is made of polysilicon semiconductor material.

7. A display panel comprising:
the array substrate according to claim 1; and
an opposed substrate opposed to the array substrate with having an inner space therebetween.
